(19) United States
(12) Patent Application Publication
(10) Pub. No.: US 2026/0186317 A1
(43) Pub. Date: Jul. 2, 2026

(54) DISPLAY DEVICE FOR DISPLAYING THREE-DIMENSIONAL IMAGES

(71) Applicant: LG Display Co., Ltd., Seoul (KR)

(72) Inventors: JoungWon Woo, Goyang-si (KR); Wook Jeon, Daejeon (KR); JuSeong Park, Gimpo-si (KR)

(73) Assignee: LG Display Co., Ltd., Seoul (KR)

(21) Appl. No.: 19/381,764

(22) Filed: Nov. 6, 2025

(30) Foreign Application Priority Data
Dec. 30, 2024 (KR) 10-2024-0200861

(51) Int. Cl. G02B 30/27

(52) U.S. Cl. CPC G02B 30/27

(57) ABSTRACT

A display device for displaying three-dimensional images can include a support plate, a base layer disposed above the support plate, a display panel disposed above the base layer and divided into a plurality of sub pixels where each sub pixel includes a display element, and a lens disposed above the display panel. The display element in at least one of the sub pixels is disposed along a focal surface of the lens and can implement a wide field of view (FoV)without optical loss.

### CROSS-REFERENCE TO RELATED APPLICATIONS

This application claims priority to Korean Patent Application No. 10-2024-0200861, filed on Dec. 30, 2024, in the Korean Intellectual Property Office, the entire disclosure of which is hereby incorporated by reference.

### BACKGROUND

### Technical Field

The present disclosure relates to a display device for displaying three-dimensional images, and more particularly, to a display device for displaying three-dimensional images including a lens.

### Discussion of the Related Art

A three-dimensional (3D) display can be defined as a system for artificially reproducing a 3D screen or image. Here, the system includes software technology for generating 3D content and hardware for implementing the content in three dimension.

A virtual 3D display (hereinafter also referred to as a three-dimensional image display device) is a system as a whole that utilizes binocular disparity (arising from the fact that the human eyes are spaced about 65 mm apart horizontally), so that a user can virtually experience a sense of depth on a planar display hardware.

In other words, due to binocular disparity, our eyes perceive slightly different images of the same object (each eye receiving different spatial information). When these two images are transmitted to the brain through the retinas, the brain fuses them, enabling us to perceive depth. Utilizing this principle, a three-dimensional image display device generates a virtual sense of depth by designing a two-dimensional display device to simultaneously display two images, one f or the left eye and one for the right eye, so that each image is delivered to the corresponding eye.

For example, the three-dimensional image display device can include a lens disposed over a display panel. The lens can extend in parallel in one direction. For example, the lens can be a lenticular lens that implements a three-dimensional image in a light field manner.

In general, the field of view (FoV) is determined by the lens shape and the optical gap. In a typical light field display (LFD) structure, when a lens with a large curvature is used to expand the FoV, the beam convergence decreases as the viewing position moves away from the front due to lens aberration, which can result in degradation of 3D image quality caused by an increase in cross talk.

### SUMMARY OF THE DISCLOSURE

An object to be achieved by the present disclosure is to provide a display device for displaying three-dimensional (3D) images (which can also be referred to as a three-dimensional image display device) capable of expanding a field of view (FoV) while having excellent 3D image quality.

Another object to be achieved by the present disclosure is to provide a display device for displaying three-dimensional images having a wide FoV for a large panel of 100 inches or more.

Another object to be achieved by the present disclosure is to provide an improved display device/apparatus for displaying three-dimensional images, which can address or overcome the limitations and disadvantages associated with the related art display devices.

Objects of the present disclosure are not limited to the above-mentioned objects, and other objects, which are not mentioned above, can be clearly understood by those skilled in the art from the following descriptions.

According to an example embodiment of the present disclosure, a display device for displaying three-dimensional images includes a support plate, a base layer disposed above the support plate, a display panel disposed above the base layer and divided into a plurality of sub pixels each including a display element, and a lens disposed above the display panel, in which the display element is disposed along a focal surface of the lens.

According to an example embodiment of the present disclosure, a display device for displaying three-dimensional images includes a display panel disposed above a base layer and divided into a plurality of sub pixels each including a display element, and a lens disposed above the display panel, in which a top surface of the base layer has an uneven profile along a curvature of the lens, and the display element is disposed along the uneven profile of the base layer.

Other detailed matters of the example embodiments of the present disclosure are included in the detailed description and the drawings.

Aspects of the present disclosure can implement a wider FoV than conventional devices, without optical loss by disposing display elements on a curved surface of a lens using a flexible display panel. In addition, the display device according to aspects of the present disclosure can suppress degradation of 3D image quality by minimizing interference between screens while maintaining beam convergence. Furthermore, the display device according to aspects of the present disclosure can implement clear 3D images not only from a front view but also from various angles.

The effects according to the present disclosure are not limited to the contents exemplified above, and more various effects are included in the present specification.

### BRIEF DESCRIPTION OF THE DRAWINGS

The above and other aspects, features and other advantages of the present disclosure will be more clearly understood from the following detailed description taken in conjunction with the accompanying drawings, in which:

FIG. 1 is a schematic view illustrating a display device for displaying three-dimensional images according to one or more example embodiments of the present disclosure;

FIG. 2 is a schematic cross-sectional view illustrating a display device for displaying three-dimensional images according to an example embodiment of the present disclosure;

FIG. 3 is a plan view showing a part of a display panel of the display device of FIG. 2 according to an example of the present disclosure;

FIG. 4 is an enlarged plan view of a stretchable display panel of a display device for displaying three-dimensional images according to an example of the present disclosure;

FIG. 5 is a cross-sectional view taken along line I-I′ of FIG. 4 according to an example of the present disclosure;

FIGS. 6 and 7 are views enlarging portion A of FIG. 2 according to an example of the present disclosure;

FIGS. 8 and 9 are graphs illustrating luminance according to a viewing angle according to one or more examples of the present disclosure;

FIG. 10 is a cross-sectional view of a display device for displaying three-dimensional images according to another example embodiment of the present disclosure; and

FIG. 11 is a plan view illustrating a part of a display panel of the display device of FIG. 10 according to an example of the present disclosure.

### DETAILED DESCRIPTION OF THE EMBODIMENTS

Advantages and characteristics of the present disclosure and a method of achieving the advantages and characteristics will be clear by referring to example embodiments described below in detail together with the accompanying drawings. However, the present disclosure is not limited to the example embodiments disclosed herein but will be implemented in various forms. The example embodiments are provided by way of example only so that those skilled in the art can fully understand the disclosures of the present disclosure and the scope of the present disclosure.

The shapes, sizes, ratios, angles, numbers, and the like illustrated in the accompanying drawings for describing the example embodiments of the present disclosure are merely examples, and the present disclosure is not limited thereto. Like reference numerals generally denote like elements throughout the specification. Further, in the following description of the present disclosure, a detailed explanation of known related technologies can be omitted to avoid unnecessarily obscuring the subject matter of the present disclosure. The terms such as “including,” “having,” and “consist of” used herein are generally intended to allow other components to be added unless the terms are used with the term “only”. Any references to singular can include plural unless expressly stated otherwise.

Components are interpreted to include an ordinary error range even if not expressly stated.

When the position relation between two parts is described using the terms such as “on”, “above”, “below”, and “next”, one or more parts can be positioned between the two parts unless the terms are used with the term “immediately” or “directly”.

When an element or layer is disposed “on,” “above,” “over”, etc. another element or layer, one or more other layers or elements can be interposed directly on the other element or therebetween.

Although the terms such as “first”, “second”, and the like are used for describing various components, these components are not confined by these terms. These terms are merely used for distinguishing one component from the other components and may not define order or sequence. Therefore, a first component to be mentioned below can be a second component in a technical concept of the present disclosure. Further, the term “can” fully encompasses all the meanings and coverages of the term “may” and vice versa.

Like reference numerals generally denote like elements throughout the specification.

A size and a thickness of each component illustrated in the drawing are illustrated for convenience of description, and the present disclosure is not limited to the size and the thickness of the component illustrated.

The features of various embodiments of the present disclosure can be partially or entirely adhered to or combined with each other and can be interlocked and operated in technically various ways, and the embodiments can be carried out independently of or in association with each other.

Hereinafter, example embodiments of the present disclosure will be described in detail with reference to the drawings. All the components of each display device/apparatus according to all embodiments of the present disclosure are operatively coupled and configured.

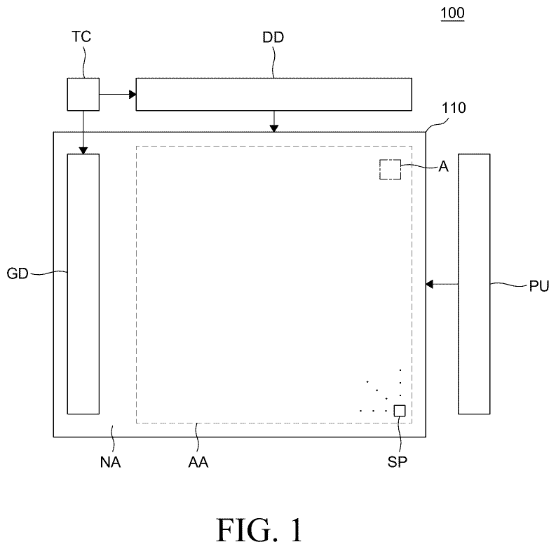

FIG. 1 is a schematic view illustrating a display device for displaying three-dimensional images according to one or more example embodiments of the present disclosure.

Referring to FIG. 1, a display device 100 for displaying three-dimensional images of an example embodiment of the present disclosure can include a display panel 110.

The display panel 110 can be of various types such as an organic light emitting display panel or a micro light emitting diode (μ-LED) display panel. Hereinafter, for convenience of description, a micro light emitting diode display panel will be described as an example.

The display panel 110 can generate an image to be provided to a user.

For example, a plurality of sub pixels SP can be disposed in a matrix form within the display panel 110. Various signals can be applied to each sub pixel SP through various signal lines GL, DL, and PL. For example, the signal lines GL, DL, and PL can include a gate line GL for applying a gate signal, a data line DL for applying a data signal, and a power voltage supply line PL for supplying a power voltage.

The gate line GL can be electrically connected to a gate driver GD. In addition, the data line DL can be electrically connected to a data driver DD.

The gate driver GD and the data driver DD can be controlled by a timing controller TC. The gate driver GD can receive a clock signal, a reset signal, and a start signal from the timing controller TC, and the data driver DD can receive digital video data and a source timing signal from the timing controller TC.

In addition, the power voltage supply line PL can be electrically connected to a power unit PU.

The display panel 110 can include an active area AA in which the plurality of sub pixels SP is disposed, and a non-active area NA located outside the active area AA. For example, the non-active area NA can be located outside the active area AA. For example, the active area AA can be enclosed by the non-active area NA entirely or in part(s).

The active area AA is an area where an image is displayed in the display device 100 for displaying three-dimensional images, and display elements and various driving elements for driving the display elements can be disposed in the active area AA.

For example, a display element can be configured as an LED element including an n-type layer, an active layer, a p-type layer, an n-electrode, and a p-electrode.

In addition, various driving elements such as thin film transistors, capacitors, and wiring lines for driving the display element can be disposed in the active area AA.

A plurality of sub pixels SP can be disposed in the active area AA. The sub pixel SP is a minimum unit constituting a screen, and each of the plurality of sub pixels SP can include a display element and a driving circuit. Each of the plurality of sub pixels SP can emit light of a wavelength different from one another. For example, the plurality of sub pixels SP can include at least one red sub pixel, a green sub pixel, and a blue sub pixel. Without being limited thereto, the plurality of sub pixels SP can further include a white sub pixel.

In addition, the driving circuit of the sub pixel SP is a circuit for controlling driving of the display element. For example, the driving circuit can include a thin film transistor and a capacitor, but is not limited thereto.

The non-active area NA is an area in which an image is not displayed, and various components for driving the plurality of sub pixels SP disposed in the active area AA can be disposed. For example, a driving IC for supplying a signal for driving the plurality of sub pixels SP and a flexible film can be disposed.

As illustrated in FIG. 1, the non-active area NA can be an area enclosing the active area AA. However, it is not limited thereto, and for example, the non-active area NA can be an area extending from the active area AA.

The gate driver GD, the data driver DD, the timing controller TC, and the power unit PU can be located outside the active area AA. For example, each of the signal lines GL, DL, and PL can include an area located on the non-active area NA.

At least one of the gate driver GD, the data driver DD, the timing controller TC, and the power unit PU can be directly disposed on the non-active area NA.

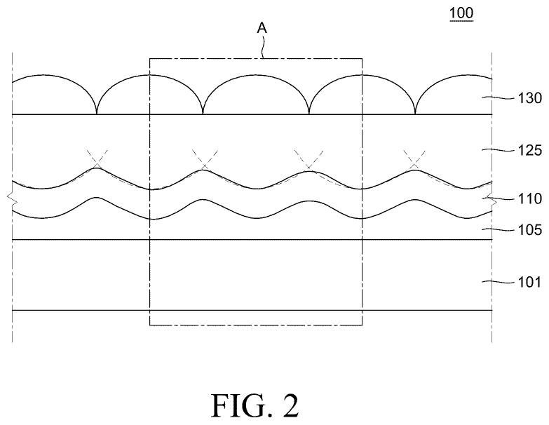

FIG. 2 is a schematic cross-sectional view illustrating a display device for displaying three-dimensional images according to an example embodiment of the present disclosure. Particularly, FIG. 2 schematically shows a part of a cross section (including portion A in FIG. 1) of the display device for displaying three-dimensional images according to an example embodiment of the present disclosure.

Referring to FIG. 2, the display device 100 for displaying three-dimensional images according to an example embodiment of the present disclosure can include a display panel 110 disposed above a support plate 101, and a lens 130 disposed above the display panel 110.

The display panel 110 can be a micro light emitting diode display panel, but is not limited thereto. The display panel 110 can be a stretchable display panel.

The support plate 101 can be disposed at the lowermost part of the display device 100 for displaying three-dimensional images. The support plate 101 can support a bottom surface of the display panel 110.

The support plate 101 can protect the display panel 110 from impact on the bottom surface. The support plate 101 can ensure impact resistance, which is the capability of the display panel 110 to withstand impact. The support plate 101 can also ensure flatness so that the display panel 110 maintains a flat state when it is not subjected to an external force that bends it.

A base layer 105 can be disposed above the support plate 101. However, the present disclosure is not limited thereto, and the base layer 105 can be omitted.

The base layer 105 can have an uneven profile on its top surface.

For example, the base layer 105 can have an uneven profile on its top surface corresponding to the curvature of the lens 130. That is, the base layer 105 can have a concave or convex shape on its top surface along the focal surface of the lens 130.

For example, the base layer 105 can be formed of an organic material.

For example, the base layer 105 can be formed through a photolithography process or an imprinting process.

A first adhesive layer can be disposed between the base layer 105 and the display panel 110, but is not limited thereto, and the display panel 110 can be directly disposed above the base layer 105.

The first adhesive layer can be disposed above the base layer 105. The first adhesive layer can be disposed over the entire top surface of the base layer 105.

For example, the first adhesive layer can be made of a transparent adhesive layer such as optical clear resin (OCR) or optical clear adhesive (OCA), but is not limited thereto. The first adhesive layer attaches the base layer 105 and the display panel 110.

The display panel 110 can be disposed above the base layer 105.

The display panel 110 can include an active area in which pixels for displaying images are provided, and a non-active area disposed so as to enclose the active area. In one example, the display panel 110 can be a micro light emitting diode (μ-LED) display panel, but is not limited thereto. The display panel 110 can be a quantum-dot display panel or an organic light emitting display panel in which an organic light emitting diode emits light by an organic emission layer to display an image.

The display panel 110 of the present disclosure can be a stretchable display panel having flexibility. The display panel 110 can be implemented using a polymer material such as polyimide which has excellent bending capability, or a plastic thin film or film. Hereinafter, a case in which the display panel 110 of the present disclosure is a stretchable display panel will be described as an example.

Meanwhile, the stretchable display panel 110 of an example embodiment of the present disclosure is characterized in that various components and layers including display elements are disposed following the uneven shape (or profile) of the top surface of the base layer 105. Specifically, the display elements and other components and layers can be disposed in concave or convex shapes according to the uneven shape formed on the top surface of the base layer 105. This is because the stretchable display panel 110 of the present disclosure has flexibility to bend or stretch by itself.

In particular, the stretchable display panel 110 according to an example embodiment of the present disclosure is characterized in that the display elements are disposed along the focal surface of the lens 130.

A planarization layer 125 can be disposed above the stretchable display panel 110.

The planarization layer 125 can planarize the unevenness of the top surface of the stretchable display panel 110.

For example, the planarization layer 125 can be formed of an organic material such as acrylic resin or epoxy resin, and for example, can be formed of photo acryl (PAC), but is not limited thereto.

A plurality of lenses 130 can be disposed above the planarization layer 125.

A second adhesive layer can be disposed between the planarization layer 125 and the lens 130, but is not limited thereto, and the lens 130 can be directly disposed above the planarization layer 125.

The second adhesive layer can be disposed above the planarization layer 125. The second adhesive layer can be disposed over the entire top surface of the planarization layer 125.

For example, the second adhesive layer can be made of a transparent adhesive layer such as optically clear resin (OCR) or optically clear adhesive (OCA), but is not limited thereto. The second adhesive layer attaches the planarization layer 125 and the lens 130.

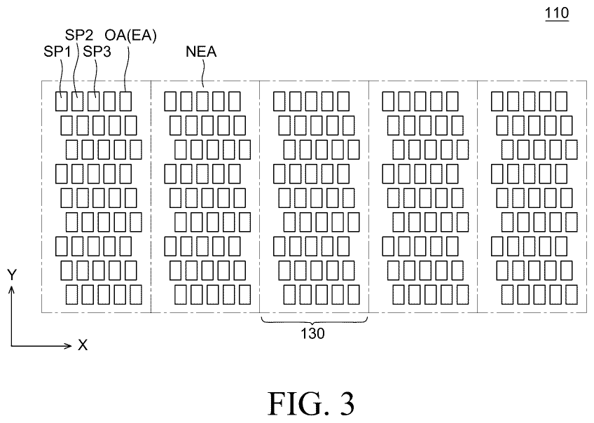

FIG. 3 is a plan view showing a part of the display panel of FIG. 2. For instance, FIG. 3 illustrates, as an example, a part of the display panel 110 in which a plurality of sub pixels SP1, SP2, and SP3 is disposed.

Particularly, FIG. 3 illustrates, as an example, a case where five sub pixels including SP1, SP2, and SP3 (SP in FIG. 1) correspond to one lens 130 in the horizontal direction, but is not limited thereto, and two or more sub pixels SP can correspond to one lens.

Referring to FIG. 3, the display panel 110 according to an example embodiment of the present disclosure can include a pixel area in which a plurality of sub pixels SP1, SP2, and SP3 is present, and a wiring area in which various signal lines are disposed.

A plurality of first sub pixels SP1, second sub pixels SP2, and third sub pixels SP3 can be disposed in the pixel area.

For example, the first sub pixel SP1 can be a red sub pixel. For example, the second sub pixel SP2 can be a green sub pixel. For example, the third sub pixel SP3 can be a blue sub pixel.

For example, the first sub pixel SP1, the second sub pixel SP2, and the third sub pixel SP3 can have a polygonal shape such as a rectangular shape, but are not limited thereto, and the first sub pixel SP1, the second sub pixel SP2, and the third sub pixel SP3 can have various shapes such as a circular or elliptical shape.

FIG. 3 illustrates a case where one first sub pixel SP1, one second sub pixel SP2, and one third sub pixel SP3 together constitute one pixel, but is not limited thereto.

Each of the sub pixels SP1, SP2, and SP3 (SP) can include an open area OA in which a portion corresponding to an emission area EA is removed (opened). The emission area EA can have a shape corresponding to the shape of the open area OA. Here, when the shape of one component corresponds to the shape of another component, it can mean that the shape of one component is identical to the shape of the other component, or that the shape is identical but the size is different, or that the shape of one component is formed by transferring the shape of another component in some way. Therefore, the shape of the emission area EA can be understood as corresponding to the shape of the open area OA, which is transferred by light emitted from the display element located substantially in the open area OA.

An area located between the emission areas EA can be defined as a non-emission area NEA.

The non-emission area NEA can correspond to an area between the lenses 130 and may not have the sub pixels SP1, SP2, and SP3 (SP) disposed therein.

The lens 130 can be disposed above the display panel 110.

The lens 130 can extend in parallel in one direction. For example, in the display device for displaying three-dimensional images according to an example embodiment of the present disclosure, the lenses 130 can be positioned in parallel in a first direction X and in a second direction Y perpendicular to the first direction X, and each sub pixel SP can extend in a direction inclined with respect to the first direction X and the second direction Y.

An image generated by light emitted from the display element of each sub pixel SP can be recognized three-dimensionally by a user through the lens 130.

The lens 130 can be a lenticular lens.

For example, the display device for displaying three-dimensional images according to an example embodiment of the present disclosure can be a light-field display apparatus (LFD) that provides a three-dimensional image to a user in a light-field manner using the lenses 130.

For example, in the first direction X, each lens 130 can overlap with a plurality of sub pixels SP. The lens 130 can be formed by a photolithography process or a reflow process, but is not limited thereto, and can be attached in the form of a film.

For example, five sub pixels SP can overlap with one of the plurality of lenses 130, but are not limited thereto. In this case, one lens 130 located above the five sub pixels SP can have a size larger than the total size of the five display elements disposed in the five sub pixels SP.

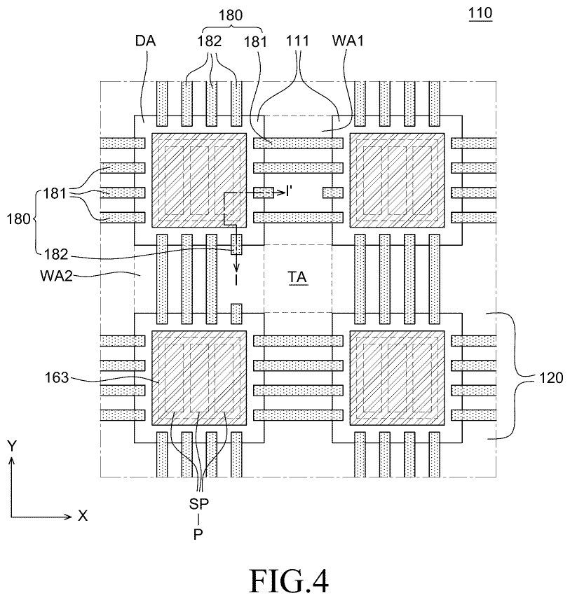

FIG. 4 is an enlarged plan view of the stretchable display panel.

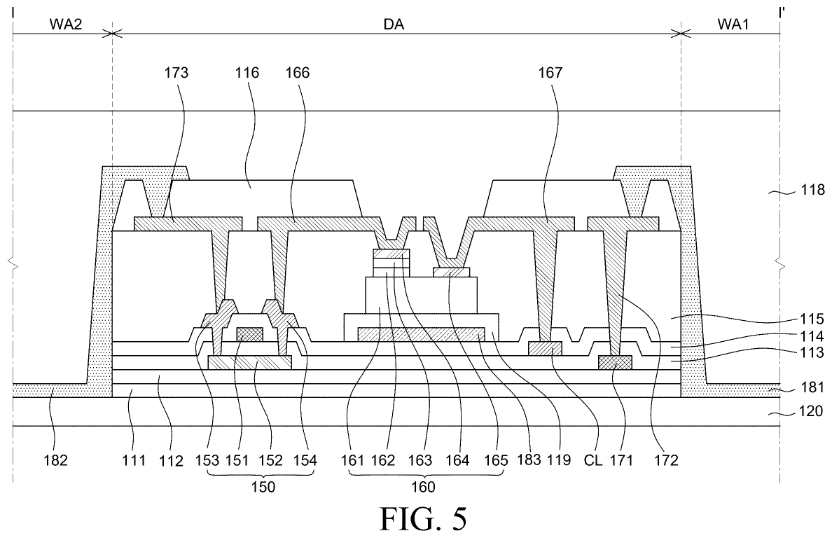

FIG. 5 is a cross-sectional view taken along line I-I′ of FIG. 4.

Particularly, FIGS. 4 and 5 illustrate a planar structure and a cross-sectional structure of the stretchable display panel 110 using micro light emitting diodes, as an example of the display panel of the present disclosure.

The stretchable display panel 110 according to an example embodiment of the present disclosure is characterized in that various components and layers including display elements are disposed in an uneven shape according to the uneven shape of the top surface of the base layer (105 in FIG. 2).

Referring to FIGS. 4 and 5, according to the stretchable display panel 110 of an example embodiment of the present disclosure, a plurality of island substrates 111 can be disposed on a lower substrate 120. The plurality of island substrates 111 can be disposed on the lower substrate 120 spaced apart from each other. For example, as illustrated in FIG. 4, the plurality of island substrates 111 can be disposed on the lower substrate 120 in a matrix form, but is not limited thereto.

The lower substrate 120 can have an unevenness corresponding to the uneven shape of the top surface of the base layer 105. For example, the top surface of the lower substrate 120 can have a concave or convex unevenness according to the uneven shape of the top surface of the base layer 105.

For example, the lower substrate 120 can have an active area and a non-active area enclosing the active area.

The active area can include a plurality of pixels P each including a plurality of sub pixels SP, and one sub pixel SP can include a display element area DA, a first wiring area WA1, a second wiring area WA2, and a transparent area TA.

Display elements and various driving elements for driving the display element can be disposed in the display element area DA.

For example, the display element can be a light emitting diode (LED) 160, but the present disclosure is not limited thereto, and it can be an organic light emitting diode including an anode, an organic emission layer, and a cathode, or a liquid crystal display element. The LED 160 can include a micro light emitting diode (μ-LED).

The plurality of LEDs 160 can be disposed following the uneven shape of the top surface of the base layer 105. That is, the plurality of LEDs 160 can be disposed along the focal surface of the lens (130 of FIG. 2).

For example, the driving element can be a transistor 150, but the present disclosure is not limited thereto.

In this case, the first wiring area WA1 can be disposed at one side of the display element area DA, and can be disposed between display element areas DA adjacent to each other in the X-axis direction.

For example, a first connection line 181 can be disposed in the first wiring area WA1. The first connection line 181 refers to a wring line among the connection lines 180 that extends in the X-axis direction.

The first connection line 181 can electrically connect pads on two island substrates 111 disposed side by side among pads on the plurality of island substrates 111 disposed adjacent to each other in the X-axis direction. The first connection line 181 can serve as a gate line or a low-potential power line, but is not limited thereto.

The first connection line 181 can be disposed following the uneven shape of the top surface of the base layer 105.

In addition, the second wiring area WA2 can be disposed at the other side of the display element area DA, and can be disposed between display element areas DA adjacent to each other in the Y-axis direction.

For example, a second connection line 182 can be disposed in the second wiring area WA2. The second connection line 182 refers to a wring line among the connection lines 180 that extends in the Y-axis direction.

The second connection line 182 can electrically connect pads on two island substrates 111 disposed side by side among pads on the plurality of island substrates 111 disposed adjacent to each other in the Y-axis direction. The second connection line 182 can serve as a data line, a high-potential power line, or a reference voltage line, but is not limited thereto.

The second connection line 182 can be disposed following the uneven shape of the top surface of the base layer 105.

In addition, the transparent area TA can be disposed between the first wiring areas WA1 adjacent to each other in the Y-axis direction and between the second wiring areas WA2 adjacent to each other in the X-axis direction. Meanwhile, areas in the first wiring area WA1 and the second wiring area WA2 other than the areas in which the first connection line 181 and the second connection line 182 are disposed can also be regarded as transparent areas since no opaque components are disposed therein.

The transparent area TA can have no opaque components and can be semi-transparent due to the lower substrate 120 made of an elastic polymer being disposed therein.

The plurality of island substrates 111 can be disposed in the display element area DA.

The top surface of the island substrate 111 can have a concave or convex shape according to the uneven shape of the top surface of the base layer 105, but is not limited thereto.

A buffer layer 112 can be disposed above the plurality of island substrates 111. For example, the buffer layer 112 can be disposed above the plurality of island substrates 111 to protect various components of the stretchable display panel 110 from permeation of moisture (H₂O) and oxygen (O₂) from the outside of the lower substrate 120 and the plurality of island substrates 111.

The buffer layer 112 can be made of an insulating material, and for example, can be a single layer or multiple layers of an inorganic layer such as silicon nitride (SiNx), silicon oxide (SiOx), or silicon oxynitride (SiON). However, the buffer layer 112 can be omitted depending on the structure or characteristics of the stretchable display panel 110.

The buffer layer 112 can have an unevenness corresponding to the uneven shape of the top surface of the base layer 105.

The buffer layer 112 can be disposed only in an area overlapping with the plurality of island substrates 111. Since the buffer layer 112 can be made of an inorganic material, cracks or other damage can easily occur during stretching of the stretchable display panel 110. Therefore, the buffer layer 112 may not be disposed in areas between the plurality of island substrates 111, and can be patterned in the shape of the plurality of island substrates 111 so as to be disposed only above the plurality of island substrates 111. Accordingly, the stretchable display panel 110 according to an example embodiment of the present disclosure can suppress damage to the buffer layer 112 even when the stretchable display panel 110 is deformed, such as being bent or stretched by disposing the buffer layer 112 only in the area overlapping with a plurality of rigid island substrates 111.

A gate pad 171 can be disposed on the buffer layer 112, but is not limited thereto. The gate pad 171 is a pad for transmitting a gate signal to the plurality of sub pixels SP. The gate pad 171 can be made of the same material as the gate electrode 151, but is not limited thereto.

The gate pad 171 can be disposed following the uneven shape of the top surface of the base layer 105.

A transistor 150 including a gate electrode 151, an active layer 152, a source electrode 153, and a drain electrode 154 can be disposed above the buffer layer 112.

The transistor 150 can be disposed following the uneven shape of the top surface of the base layer 105.

The transistor 150 can be disposed in the display element area DA.

For example, the active layer 152 can be disposed on the buffer layer 112, and a gate insulating layer 113 for insulating the active layer 152 from the gate electrode 151 can be disposed on the active layer 152.

The gate insulating layer 113 can have an unevenness corresponding to the uneven shape of the top surface of the base layer 105.

A common line CL can be disposed on the gate insulating layer 113.

The common line CL can be disposed following the uneven shape of the top surface of the base layer 105.

The common line CL is a wiring line for applying a common voltage to the plurality of sub pixels SP. The common line CL can be made of the same material as the source electrode 153 and the drain electrode 154 of the transistor 150, but is not limited thereto.

In addition, an interlayer insulating layer 114 for insulating the gate electrode 151 from the source electrode 153 and the drain electrode 154 can be disposed on the gate insulating layer 113. In addition, the source electrode 153 and the drain electrode 154, each in contact with the active layer 152, can be disposed on the interlayer insulating layer 114.

The interlayer insulating layer 114 can have an unevenness corresponding to the uneven shape of the top surface of the base layer 105.

The gate insulating layer 113 and the interlayer insulating layer 114 can be patterned so as to be disposed only in an area overlapping with the plurality of island substrates 111. Since the gate insulating layer 113 and the interlayer insulating layer 114 can also be made of an inorganic material, similarly to the buffer layer 112, cracks or other damage can easily occur during stretching of the stretchable display panel 110. Therefore, the gate insulating layer 113 and the interlayer insulating layer 114 may not be disposed in areas between the plurality of island substrates 111, and can be patterned in the shape of the plurality of island substrates 111 so as to be disposed only above the plurality of island substrates 111.

In FIG. 5, for convenience of description, only the driving transistor among various transistors that can be included in the stretchable display panel 110 is illustrated, but is not limited thereto, and switching transistors, capacitors, and the like can also be included in the display device. In addition, although the transistor 150 is described herein as having a coplanar structure, various transistors such as a staggered structure can also be used.

A reflective layer 183 can be disposed on the interlayer insulating layer 114.

The reflective layer 183 can be disposed following the uneven shape of the top surface of the base layer 105.

The reflective layer 183 is a layer for reflecting light, among the light emitted from the LED 160, which is emitted toward the lower substrate 120, upward to the upper part of the stretchable display panel 110 to emit the light outward. The reflective layer 183 can be made of a metal material having high reflectivity.

An adhesive layer 119 covering the reflective layer 183 can be disposed on the reflective layer 183.

The adhesive layer 119 can have an unevenness corresponding to the uneven shape of the top surface of the base layer 105.

The adhesive layer 119 is a layer for attaching the LED 160 above the reflective layer 183, for insulating the reflective layer 183 made of a metal material from the LED 160. For example, the adhesive layer 119 can be made of a thermosetting material or a photo-curable material, but is not limited thereto. In FIG. 5, the adhesive layer 119 is illustrated as being disposed to cover only the reflective layer 183, but the placement position of the adhesive layer 119 is not limited thereto.

The LED 160 can be disposed above the adhesive layer 119. The LED 160 can be disposed so as to overlap the reflective layer 183.

As described above, the plurality of LEDs 160 can be disposed following the uneven shape of the top surface of the base layer 105. That is, the plurality of LEDs 160 can be disposed along the focal surface of the lens 130.

The LED 160 can be disposed in the display element area DA.

The LED 160 can include an n-type layer 161, an active layer 162, a p-type layer 163, an n-electrode 165, and a p-electrode 164. Hereinafter, a case in which the LED 160 of a lateral structure is used will be described as an example, but is not limited thereto.

For example, the n-type layer 161 of the LED 160 can be disposed on the adhesive layer 119 so as to overlap the reflective layer 183. The n-type layer 161 can be formed by doping an n-type impurity into gallium nitride having excellent crystallinity. The active layer 162 can be disposed on the n-type layer 161. The active layer 162 is an emission layer that emits light in the LED 160, and can be made of a nitride semiconductor such as indium gallium nitride. The p-type layer 163 can be disposed on the active layer 162. The p-type layer 163 can be formed by doping a p-type impurity into gallium nitride. However, the materials of the n-type layer 161, the active layer 162, and the p-type layer 163 are not limited thereto.

A p-electrode 164 can be disposed on the p-type layer 163 of the LED 160. An n-electrode 165 can be disposed on the n-type layer 161 of the LED 160. The n-electrode 165 can be disposed spaced apart from the p-electrode 164. For example, the LED 160 can be manufactured by sequentially laminating the n-type layer 161, the active layer 162, and the p-type layer 163, etching predetermined portions of the active layer 162 and the p-type layer 163, and forming the n-electrode 165 and the p-electrode 164. In this case, the predetermined portion can serve as a space for spacing apart the n-electrode 165 and the p-electrode 164, and can be etched so that a part of the n-type layer 161 is exposed. That is, the surfaces of the LED 160 on which the p-electrode 164 and the n-electrode 165 are disposed may not be flat surfaces, but can have different height levels. Accordingly, the p-electrode 164 can be disposed on the p-type layer 163, and the n-electrode 165 can be disposed on the n-type layer 161, and the p-electrode 164 and the n-electrode 165 can be disposed spaced apart from each other at different height levels.

In addition, the n-electrode 165 can be disposed closer to the reflective layer 183 than the p-electrode 164. The n-electrode 165 and the p-electrode 164 can be made of a conductive material, and for example, can be made of a transparent conductive oxide. The n-electrode 165 and the p-electrode 164 can be made of the same material, but are not limited thereto.

A planarization layer 115 can be disposed above the interlayer insulating layer 114 and the adhesive layer 119. The planarization layer 115 can be disposed so as to planarize an upper surface of the planarization layer 115 in an area other than the area where the LED 160 is disposed. The planarization layer 115 can include two or more layers.

The planarization layer 115 can have an unevenness corresponding to the uneven shape of the top surface of the base layer 105.

In some example embodiments of the present disclosure, an additional insulating layer can be disposed between the transistor 150 and the planarization layer 115. That is, in order to protect the transistor 150 from permeation of moisture or oxygen, an additional insulating layer covering the transistor 150 can be disposed. The additional insulating layer can be made of an inorganic material, can be a single layer or a multi-layer, and can be a passivation layer, but the present disclosure is not limited thereto.

A first electrode 166 and a second electrode 167 can be disposed above the planarization layer 115. The first electrode 166 is an electrode for electrically connecting the transistor 150 and the LED 160.

The first electrode 166 and the second electrode 167 can be disposed following the uneven shape of the top surface of the base layer 105.

The first electrode 166 can be connected to the p-electrode 164 of the LED 160 through a contact hole formed in the planarization layer 115. In addition, the first electrode 166 can be connected to the drain electrode 154 of the transistor 150 through contact holes formed in the planarization layer 115 and the interlayer insulating layer 114. However, without being limited thereto, depending on the type of the transistor 150, the first electrode 166 can also be connected to the source electrode 153 of the transistor 150.

The p-electrode 164 of the LED 160 and the drain electrode 154 of the transistor 150 can be electrically connected by the first electrode 166.

In addition, the second electrode 167 is an electrode for electrically connecting the LED 160 and the common line CL. For example, the second electrode 167 can be connected to the common line CL through a contact hole formed in the planarization layer 115 and the interlayer insulating layer 114, and can be connected to the n-electrode 165 of the LED 160 through a contact hole formed in the planarization layer 115. Accordingly, the common line CL and the n-electrode 165 of the LED 160 can be electrically connected.

When the stretchable display panel 110 is turned on, voltages of different levels can be applied to the drain electrode 154 of the transistor 150 and the common line CL, respectively. The voltage applied to the drain electrode 154 of the transistor 150 can be applied to the first electrode 166, and a common voltage can be applied to the second electrode 167. The voltages of different levels can be applied to the p-electrode 164 and the n-electrode 165 through the first electrode 166 and the second electrode 167, and thus, the LED 160 can emit light.

In FIG. 5, a case where the transistor 150 is electrically connected to the p-electrode 164 and the common line CL is electrically connected to the n-electrode 165 is illustrated as an example, but is not limited thereto, and the transistor 150 can be electrically connected to the n-electrode 165 and the common line CL can be electrically connected to the p-electrode 164.

A data pad 173 and a connection pad 172 can be disposed above the planarization layer 115.

The data pad 173 and the connection pad 172 can be disposed following the uneven shape of the top surface of the base layer 105.

The data pad 173 can transmit a data signal from the connection line 180 functioning as a data line to the plurality of sub pixels SP. The data pad 173 can be connected to the source electrode 153 of the transistor 150 through a contact hole formed in the planarization layer 115.

In addition, the connection pad 172 can transmit a gate signal from the connection line 180 functioning as a gate line to the plurality of sub pixels SP. The connection pad 172 can be connected to the gate pad 171 through a contact hole formed in the planarization layer 115 and the interlayer insulating layer 114, and can transmit the gate signal to the gate pad 171. The connection pad 172 can be made of the same material as the data pad 173, but is not limited thereto.

A bank 116 can be disposed on the planarization layer 115, the first electrode 166, and the second electrode 167. The bank 116 can be disposed so as to overlap the end of the reflective layer 183, and a portion of the reflective layer 183 not overlapping the bank 116 can be defined as an emission area. The bank 116 can be made of an organic insulating material and can be made of the same material as the planarization layer 115. In addition, the bank 116 can be configured to include a black material in order to suppress color mixing from occurring by light emitted from the LED 160 being transmitted to an adjacent sub pixel SP. For example, the bank 116 can be made of polyimide, acrylic resin, or benzocyclobutene (BCB) resin, but is not limited thereto.

The bank 116 can have an unevenness corresponding to the uneven shape of the top surface of the base layer 105.

The stretchable display panel 110 according to an example embodiment of the present disclosure can include the LED 160. In this case, since the LED 160 is made of an inorganic material rather than an organic material, it has excellent reliability and a longer lifespan than a liquid crystal display element or an organic light emitting diode. In addition, the LED 160 has not only a fast lighting speed, but also low power consumption, strong impact resistance, high stability, and excellent luminous efficiency, making it suitable for high-brightness image display and application to very large-sized screens. Particularly, since the LED 160 is made of an inorganic material rather than an organic material, an encapsulation layer required when using an organic light emitting diode may not be used. Accordingly, the encapsulation layer, which can be easily damaged due to crack generation during stretching of the stretchable display panel 110, can be omitted. Therefore, by using the LED 160 as the display element, the stretchable display panel 110 according to an example embodiment of the present disclosure can omit the use of an encapsulation layer that can be damaged when the stretchable display panel 110 is bent or stretched. Since the LED 160 is made of an inorganic material rather than an organic material, the display element of the stretchable display panel 110 according to an example embodiment of the present disclosure can be protected from moisture or oxygen and can have excellent reliability.

The stretchable display panel 110 according to an example embodiment of the present disclosure can have a structure in which a plurality of island substrates 111 having relatively rigidity is disposed on the lower substrate 120 having relatively flexibility spaced apart from each other. Accordingly, in the stretchable display panel 110 according to an example embodiment of the present disclosure, even when a user stretches or bends the stretchable display panel 110, the stretchable display panel 110 can have a structure that can be more easily deformed, and the stretchable display panel 110 can have a structure capable of minimizing damage to the components of the stretchable display panel 110 during deformation.

The connection line 180 refers to a wiring line that electrically connects pads above the plurality of island substrates 111. The connection line 180 can include a first connection line 181 and a second connection line 182. The first connection line 181 refers to a wiring line among the connection lines 180 that extends in the X-axis direction, and the second connection line 182 refers to a wiring line among the connection lines 180 that extends in the Y-axis direction.

In a general stretchable display panel, various wiring lines such as a plurality of gate lines and a plurality of data lines are disposed extending between a plurality of sub pixels, and a plurality of sub pixels is connected to one signal line. Accordingly, in a general stretchable display device, various wiring lines such as gate lines, data lines, high-potential power lines, and reference voltage lines extend from one side to the other side of the stretchable display device on the substrate without being disconnected.

In contrast, in the stretchable display panel 110 according to an example embodiment of the present disclosure, various wiring lines such as gate lines, data lines, high-potential power lines, and reference voltage lines made of a metal material can be disposed only above the plurality of island substrates 111. That is, in the stretchable display panel 110 according to an example embodiment of the present disclosure, various wiring lines made of a metal material can be disposed only above the plurality of island substrates 111 and may not contact the lower substrate 120. Accordingly, the various wiring lines can be patterned to correspond to the plurality of island substrates 111 and can be disposed discontinuously.

In the stretchable display panel 110 according to an example embodiment of the present disclosure, in order to connect such discontinuous wiring lines, pads above two island substrates 111 adjacent to each other can be connected by the connection line 180. That is, the connection line 180 can electrically connect pads above two island substrates 111 adjacent to each other. Therefore, the stretchable display panel 110 of the present disclosure can include a plurality of connection lines 180 to electrically connect various wiring lines such as gate lines, data lines, high-potential power lines, and reference voltage lines between the plurality of island substrates 111. For example, gate lines can be disposed above the plurality of island substrates 111 disposed adjacent to each other in the X-axis direction, and gate pads 171 can be disposed at both ends of the gate lines. In this case, the plurality of gate pads 171 above the plurality of island substrates 111 disposed adjacent to each other in the X-axis direction can be connected to each other by the connection line 180 functioning as a gate line. Accordingly, the gate lines disposed above the plurality of island substrates 111 and the connection line 180 disposed above the lower substrate 120 can function as one gate line. That is, all the various wiring lines that can be included in the stretchable display panel 110, such as data lines, high-potential power lines, and reference voltage lines, can also function as one wiring line through the connection line 180 as described above.

The first connection line 181 can electrically connect pads above two island substrates 111 disposed side by side among pads above the plurality of island substrates 111 disposed adjacent to each other in the X-axis direction. The first connection line 181 can serve as a gate line or a low-potential power line, but is not limited thereto. For example, the first connection line 181 can function as a gate line and can electrically connect gate pads 171 above two island substrates 111 disposed side by side in the X-axis direction through a contact hole formed in the bank 116. Accordingly, as described above, the gate pads 171 above the plurality of island substrates 111 disposed in the X-axis direction can be connected to each other by the first connection line 181 functioning as a gate line, and one gate signal can be transmitted.

The first connection line 181 can be disposed in the first wiring area WA1.

The second connection line 182 can electrically connect pads above two island substrates 111 disposed side by side among pads above the plurality of island substrates 111 disposed adjacent to each other in the Y-axis direction. The second connection line 182 can serve as a data line, a high-potential power line, or a reference voltage line, but is not limited thereto. For example, the second connection line 182 can function as a data line and can electrically connect data pads 173 above two island substrates 111 disposed side by side in the Y-axis direction through a contact hole formed in the bank 116. Accordingly, as described above, the data pads 173 above the plurality of island substrates 111 disposed in the Y-axis direction can be connected to each other by the plurality of second connection lines 182 functioning as data lines, and one data signal can be transmitted.

The second connection line 182 can be disposed in the second wiring area WA2.

The connection line 180 can include a base polymer and conductive particles. For example, the first connection line 181 can include a base polymer and conductive particles, and the second connection line 182 can include a base polymer and conductive particles.

The first connection line 181 can be disposed in contact with the top surface and side surface of the bank 116 disposed above the island substrate 111, the planarization layer 115, the interlayer insulating layer 114, the buffer layer 112, and the side surface of the plurality of island substrates 111, and can be disposed so as to extend to the top surface of the lower substrate 120. Accordingly, the first connection line 181 can be in contact with the top surface of the lower substrate 120, in contact with the side surface of an adjacent island substrate 111, and simultaneously in contact with the side surfaces of the buffer layer 112, the gate insulating layer 113, the interlayer insulating layer 114, the planarization layer 115, and the bank 116 disposed above the adjacent island substrate 111. In addition, the first connection line 181 can be in contact with the connection pad 172 disposed above the adjacent island substrate 111, but is not limited thereto.

In this case, the base polymer of the first connection line 181 can be made of an insulating material capable of bending or stretching similarly to the lower substrate 120. The base polymer can include, for example, styrene-butadiene-styrene (SBS), but is not limited thereto. Accordingly, when the stretchable display panel 110 is bent or stretched, the base polymer may not be damaged. The base polymer can be formed by coating a material constituting the base polymer above the lower substrate 120 and the island substrate 111 or by applying the material using a slit, but is not limited thereto.

The conductive particles of the first connection line 181 can be dispersed in the base polymer. In this case, the first connection line 181 can include conductive particles dispersed at a certain concentration in the base polymer. The first connection line 181 can be formed, for example, by uniformly stirring conductive particles into the base polymer and then coating and curing the base polymer containing the dispersed conductive particles above the lower substrate 120 and the island substrate 111, but is not limited thereto. The conductive particles can include at least one of silver (Ag), gold (Au), and carbon, but are not limited thereto.

The conductive particles dispersed in the base polymer of the first connection line 181 can form a conductive path that electrically connects the connection pads 172 respectively disposed above the adjacent island substrates 111. In addition, the conductive particles can electrically connect the gate pad 171 formed above the outermost island substrate 111 among the plurality of island substrates 111 with a pad disposed in the non-active area NA to form a conductive path.

The base polymer of the first connection line 181 and the conductive particles dispersed in the base polymer can connect the pads disposed above the adjacent island substrates 111 to each other in a straight-line shape. For this purpose, during the manufacturing process, the base polymer can be formed in a straight-line shape connecting the pads disposed on each of the plurality of island substrates 111. Accordingly, the conductive path formed by the conductive particles dispersed in the base polymer can also have a straight-line shape. However, the forming process and shape of the base polymer and conductive particles of the first connection line 181 are not limited thereto.

The second connection line 182 can be formed in contact with the top surface and side surface of the bank 116 disposed above the island substrate 111, the planarization layer 115, the interlayer insulating layer 114, the buffer layer 112, and the side surface of the plurality of island substrates 111, and can be formed so as to extend to the top surface of the lower substrate 120. Accordingly, the second connection line 182 can be in contact with the top surface of the lower substrate 120, in contact with the side surface of an adjacent island substrate 111, and simultaneously in contact with the side surfaces of the buffer layer 112, the data insulating layer 113, the interlayer insulating layer 114, the planarization layer 115, and the bank 116 disposed above the adjacent island substrate 111. In addition, the second connection line 182 can be in contact with the data pad 173 disposed above the adjacent island substrate 111, but is not limited thereto.

In addition, the base polymer of the second connection line 182 can be made of an insulating material capable of bending or stretching similarly to the lower substrate 120, and can be the same material as the base polymer of the first connection line 181. The base polymer can include, for example, SBS, but is not limited thereto.

The conductive particles of the second connection line 182 can be dispersed in the base polymer. For example, the second connection line 182 can include conductive particles dispersed at a certain concentration in the base polymer. The concentration of the conductive particles dispersed above the base polymer of the second connection line 182 and the concentration of the conductive particles dispersed in the lower part of the base polymer can be substantially the same. In addition, the manufacturing process of the second connection line 182 can be the same as that of the first connection line 181 and can be performed simultaneously.

The conductive particles dispersed in the base polymer of the second connection line 182 can form a conductive path that electrically connects the data pads 173 respectively disposed above the adjacent island substrates 111. In addition, the conductive particles can electrically connect the data pad 173 formed above the outermost island substrate 111 among the plurality of island substrates 111 with a pad disposed in the non-active area NA to form a conductive path.

The base polymer of the second connection line 182 and the conductive particles dispersed in the base polymer can connect the pads disposed above the adjacent island substrates 111 to each other in a straight-line shape. For this purpose, during the manufacturing process, the base polymer can be formed in a straight-line shape connecting the pads disposed above each of the plurality of island substrates 111. Accordingly, the conductive path formed by the conductive particles dispersed in the base polymer can also have a straight-line shape. However, the forming process and shape of the base polymer and conductive particles of the second connection line 182 are not limited thereto.

In some example embodiments of the present disclosure, the conductive particles dispersed in the base polymer of the connection line 180 can be dispersed to be disposed so as to have a concentration gradient within the base polymer.

For example, the concentration of the conductive particles can decrease from the upper part toward the lower part of the base polymer, so that the conductivity due to the conductive particles can be highest in the upper part of the base polymer. In this case, specifically, the conductive particles can be injected on the base polymer using an ink printing process employing a conductive precursor on the top surface of the base polymer so as to be dispersed therein.

During the process of injecting the conductive particles on the base polymer, the polymer can swell several times, allowing the conductive particles to permeate into void spaces of the base polymer. When the base polymer on which the conductive particles are injected is dipped into a reducing agent or reduced by vapor, the connection line 180 can be formed.

Accordingly, the permeation area of the upper part of the base polymer can have a concentration of conductive particles high enough to form a conductive path.

The thickness of the penetration area in which the conductive particles of the upper part of the base polymer are dispersed at a high concentration can vary depending on the time and intensity of injection of the conductive particles on the top surface of the base polymer. For example, when the time or intensity of injection of the conductive particles on the top surface of the base polymer increases, the thickness of the permeation area can become thicker. In addition, each conductive particle can be in contact with another conductive particle in the upper part of the base polymer, and thus a conductive path can be formed through the conductive particles in contact with each other, allowing an electrical signal to be transmitted.

In some example embodiments of the present disclosure, the base polymer of the connection line 180 can be formed as a single layer above the lower substrate 120 between the adjacent island substrates 111. Specifically, the base polymer can be disposed in contact with the lower substrate 120 as a single layer in an area between the island substrates 111 closest to each other in the X-axis direction. The base polymer can be formed so as to overlap with all the plurality of pads disposed side by side on one side of one island substrate 111. Then, the conductive particles can be separately formed so as to form a plurality of conductive paths corresponding to the respective pads on the single layer of the base polymer. Accordingly, the conductive path formed by the conductive particles can connect the pads disposed on the adjacent island substrates 111 to each other in a straight-line shape, and for example, the conductive particles can be injected to form four conductive paths on the top surface of the base polymer disposed as a single layer between the plurality of island substrates 111.

In some example embodiments of the present disclosure, the base polymer of the connection line 180 can be disposed over the entire area excluding the areas where the plurality of island substrates 111 is disposed. The base polymer can be disposed as a single layer in contact with the lower substrate 120 in all areas except for the areas overlapping the plurality of rigid substrates, that is, the plurality of island substrates 111. Accordingly, in the lower substrate 120, areas other than areas overlapping with the plurality of island substrates 111 can be covered by the base polymer, and the base polymer can contact the pads of the plurality of island substrates 111, so that a portion of the base polymer can be disposed to cover the edges of the plurality of island substrates 111. Then, the conductive particles can form a conductive path connecting the pads on the adjacent plurality of island substrates 111 over the base polymer.

When the base polymer is disposed as a single layer over the entire area of the lower substrate 120 excluding the areas where the plurality of island substrates 111 is disposed, the base polymer can be formed by being applied to the entire area of the lower substrate 120 excluding the areas where the plurality of island substrates 111 is disposed. Therefore, a separate process for patterning the base polymer may not be required or used. Accordingly, the manufacturing process of the base polymer and the connection line can be simplified, and process cost and time can be reduced.

By disposing the base polymer as a single layer over the entire area of the lower substrate 120 excluding the areas where the plurality of island substrates 111 is disposed, the force applied when the stretchable display panel 110 is bent or stretched can be dispersed. In addition, in some example embodiments of the present disclosure, the top surface of the base polymer of the connection line 180 can be flat.

For example, unlike that shown in FIG. 5, the top surface of the base polymer of the connection line 180, such as gate lines and data lines, can be higher than the top surface of the planarization layer 115 above the plurality of island substrates 111. The top surface of the base polymer can be higher than the top surface of the bank 116 above the plurality of island substrates 111. Accordingly, in the base polymer of the connection line 180, the height of the top surface in a portion of the base polymer overlapping the plurality of island substrates 111 and the height of the top surface in an area disposed between the plurality of island substrates 111 can be the same. Therefore, the top surface of the connection line 180 can be flat. As a result, the top surface of the conductive particles dispersed over the base polymer can have a straight-line shape without curvature in the cross-sectional view.

A step can be present between the top surface of the bank 116 and the top surface of the lower substrate 120 due to various components on the plurality of island substrates 111 disposed to be spaced apart above the lower substrate 120. In this case, the base polymer itself can be broken due to the step on the top surface of the base polymer, and thus the electrical path between pads disposed on adjacent island substrates 111 can be blocked, and the defect rate of the stretchable display device can be increased.

In this case, when the top surface of the base polymer is flat, the step between the top surfaces of the elements disposed above the plurality of island substrates 111 and the top surface of the lower substrate 120 on which the plurality of island substrates 111 is not disposed can be eliminated. Accordingly, even if the stretchable display panel 110 is bent or stretched, it is possible to suppress the connection line 180 including the base polymer and the conductive particles from being broken due to the step. In addition, by having the top surface of the base polymer flat, it is possible to minimize damage to the connection line 180 during the manufacturing process of the stretchable display panel 110.

As described above, since the stretchable display device should have a property of easily bending or stretching, a substrate having relatively high flexibility with a low modulus can be used. For example, a substrate can be manufactured using a flexible material such as polydimethylsiloxane (PDMS) having a low modulus. When such a low modulus material is used as a lower substrate on which a display element is disposed during manufacture, the substrate can be damaged by heat generated during a process for forming a transistor or display element, for example, a temperature of 100° C. or higher, due to the heat-sensitive nature of the low modulus material.

Therefore, the display element should be formed above a substrate made of a material capable of withstanding high temperatures so as to prevent damage to the substrate during the process of forming the display element. Accordingly, attempts have been made to form a substrate using a material such as polyimide (PI), which can withstand high temperatures generated during the manufacturing process. However, materials capable of withstanding high temperatures have a high modulus and therefore lack high flexibility, causing difficulty in bending or stretching the substrate during stretching of the stretchable display device.

Therefore, in the stretchable display panel 110 according to an example embodiment of the present disclosure, the plurality of island substrates 111, which are rigid substrates, can be disposed only in areas where the transistor 150 or LED 160 is disposed so as to suppress the plurality of island substrates 111 from being damaged by high temperatures during manufacture of the transistor 150 or the LED 160.

In addition, in the stretchable display panel 110 according to an example embodiment of the present disclosure, the lower substrate 120, which is a flexible substrate, can be disposed below the plurality of island substrates 111. Therefore, since the remaining areas of the lower substrate 120 and the upper substrate excluding the areas overlapping the plurality of island substrates 111 can be easily stretched or bent, the stretchable display panel 110 can be implemented. Furthermore, transistors 150, light emitting diodes 160, and the like disposed above the plurality of rigid island substrates 111 can be suppressed from being damaged as the stretchable display panel 110 is bent or stretched.

Meanwhile, when the stretchable display panel is bent or stretched, the lower substrate made of a flexible substrate can be deformed, whereas the island substrate made of a rigid substrate on which the display element is disposed may not be deformed. In this case, if the wiring line connecting the respective pads disposed above the plurality of island substrates is not made of a material that can be easily bent or stretched, the wiring line can be damaged, for example, by cracking due to deformation of the lower substrate.

In contrast, in the stretchable display panel 110 according to an example embodiment of the present disclosure, the connection line 180 including a base polymer and conductive particles can electrically connect the pads disposed on each of the plurality of island substrates 111. The base polymer can have flexibility that allows easy deformation. Accordingly, even if the stretchable display panel 110 is bent or stretched, the connection line 180 including the base polymer can be easily deformed in an area between the plurality of island substrates 111.

In addition, in the stretchable display panel 110 according to an example embodiment of the present disclosure, since the connection line 180 includes conductive particles, a conductive path made of the conductive particles may not be damaged by cracking or the like even when the base polymer is deformed. For example, when the stretchable display panel 110 is bent or stretched, the lower substrate 120, which is a flexible substrate, may be deformed in the remaining area excluding the area where the plurality of island substrates 111, which are rigid substrates, are disposed. In this case, the distance between the plurality of conductive particles disposed above the deforming lower substrate 120 can change. At this time, the concentration of the plurality of conductive particles disposed above the base polymer to form a conductive path can be maintained high so that an electrical signal can be transmitted even if the distance between the plurality of conductive particles increases. Therefore, even if the base polymer is bent or stretched, the conductive path formed by the plurality of conductive particles can smoothly transmit an electrical signal, and even when the stretchable display panel 110 is bent or stretched, the electrical signal can be transmitted between each pad.

Furthermore, in the stretchable display panel 110 according to an example embodiment of the present disclosure, since the connection line 180 includes a base polymer and conductive particles, the connection line 180 connecting the respective pads disposed above the adjacent plurality of island substrates 111 can be disposed in the shortest distance, that is, in a straight-line shape. That is, the stretchable display panel 110 can be implemented even if the connection line 180 is not formed in a bent shape. The conductive particles of the connection line 180 can be dispersed in the base polymer to form a conductive path. In addition, as the stretchable display panel 110 is bent or stretched, the conductive path formed by the conductive particles can be bent or stretched. In this case, although the distance between the conductive particles can change, the conductive path formed by the conductive particles can still transmit an electrical signal. Accordingly, in the stretchable display panel 110 according to an example embodiment of the present disclosure, the space occupied by the connection line 180 can be minimized.

An upper adhesive layer 118 can be disposed on the lower substrate 120 configured as described above. However, the present disclosure is not limited thereto, and the upper adhesive layer 118 can be replaced with a planarization layer (125 of FIG. 2).

Meanwhile, as described above, when a lens with a large curvature is used to expand the field of view (FoV) of the light-field display device, the beam convergence decreases as the viewing direction deviates from the front due to lens aberration, causing degradation of 3D image quality due to increased crosstalk.

Accordingly, in an example embodiment of the present disclosure, a display element, for example, the LED 160, is disposed on the focal surface of the lens 130 by using the stretchable display panel 110. Thus, a wider FoV than before can be implemented without optical loss. This will be described in more detail with reference to the drawings.

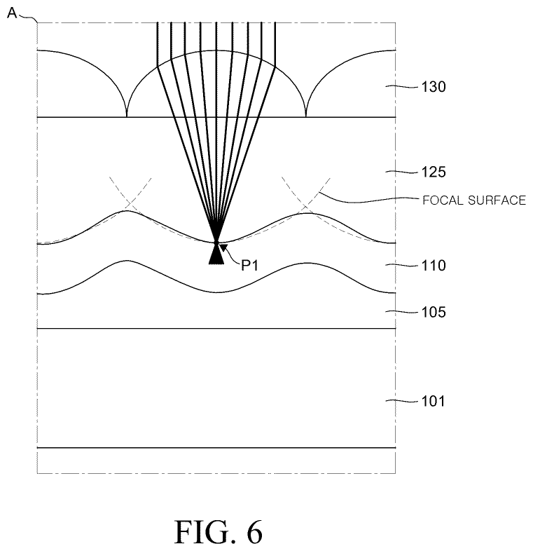

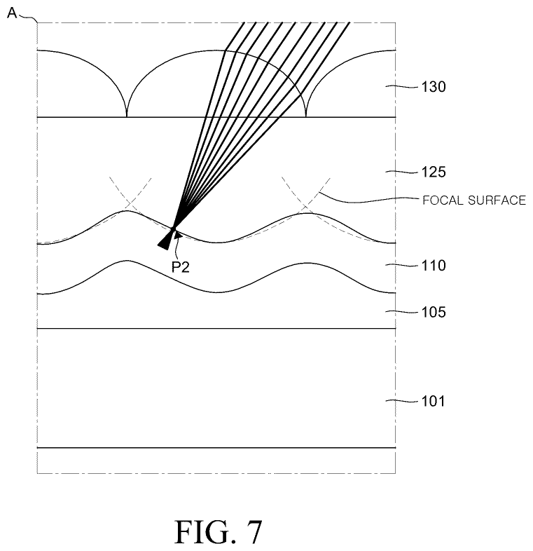

FIGS. 6 and 7 are views enlarging portion A of FIG. 2 according to an example of the present disclosure.

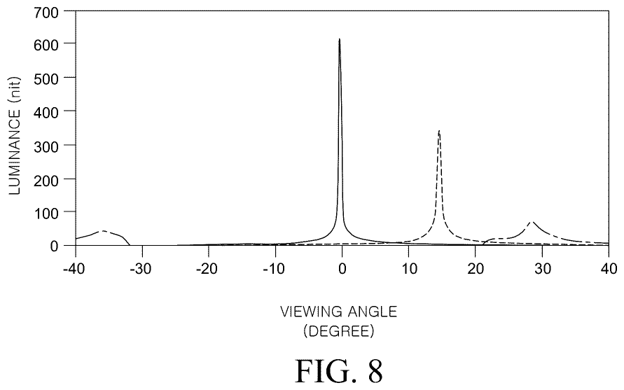

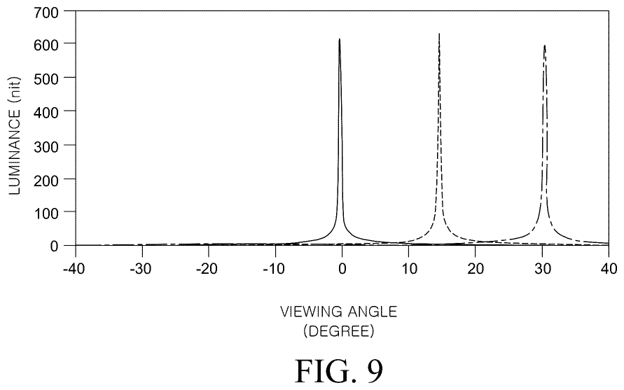

FIGS. 8 and 9 are graphs illustrating luminance according to a viewing angle of a display device according to a comparative embodiment and an example embodiment of the present disclosure, respectively.

Particularly, FIG. 6 illustrates, as an example, a profile of light emitted from a display element located at a focal surface P1 of the lens 130 in the front direction of the lens 130, and FIG. 7 illustrates, as an example, a profile of light emitted from a display element located at a focal surface P2 of the lens 130 in the viewing angle direction of the lens 130.

FIG. 8 illustrates, as an example, the luminance according to the viewing angle in a comparative embodiment, and FIG. 9 illustrates, as an example, the luminance according to the viewing angle in an example embodiment of the present disclosure.

When a lenticular lens with a large curvature is applied, FoV expansion is possible even with a short lens pitch. However, the larger the curvature, the greater the difference in focal distance between the front and viewing angle directions due to an increase in lens aberration, which causes a decrease in beam convergence and an increase in crosstalk.

On the other hand, when a lenticular lens with a small curvature is used, the beam convergence in the viewing angle direction is improved, but the lens pitch increases, which has the disadvantage of reducing the 2D resolution.

In general, since sub pixels disposed in the display panel exist on a flat surface, when a lens with a large curvature is used, the focal surface can move farther away in the viewing angle direction.

In this regard, referring to FIGS. 6 and 7, the present disclosure is characterized in that display elements are disposed on the focal surfaces P1 and P2 of the lens 130 to compensate for aberrations of the lens 130 with a large curvature.

Since this makes it possible to compensate for aberration, not only the light emitted from a display element located at the focal surface P1 in the front direction of the lens 130 but also the light emitted from a display element located at the focal surface P2 in the viewing angle direction of the lens 130 can have improved beam convergence.

Referring to FIG. 8, in the case of the comparative embodiment, it can be seen that the beam convergence decreases as the viewing angle direction shifts from 0° in the front direction to 30°. That is, as the viewing angle increases, the beam convergence decreases rapidly.

Referring to FIG. 9, in the case of the example embodiment of the present disclosure, it can be seen that the beam convergence hardly decreases as the viewing angle direction shifts from 0° in the front direction to 30°. That is, it can be seen that even if the viewing angle increases, the change in beam convergence is small, which is an improved property.

Meanwhile, the present disclosure can be applied to a large display device such as a tiling display device, which will be described in detail with reference to the drawings.

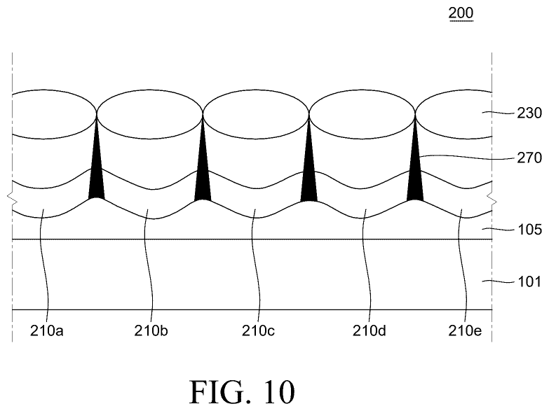

FIG. 10 is a cross-sectional view of a display device according to another example embodiment of the present disclosure.

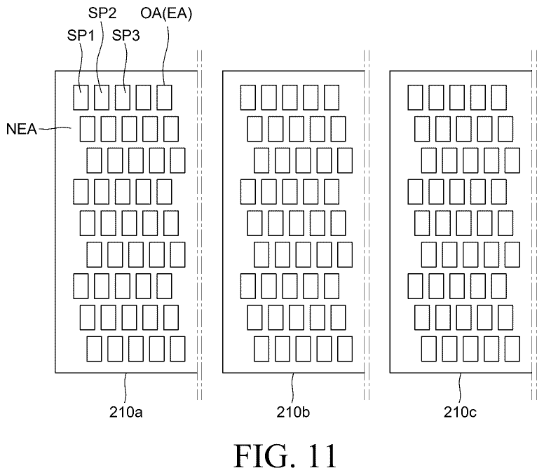

FIG. 11 is a plan view illustrating a part of a display panel of the display device of FIG. 10.

In a display device 200 according to another example embodiment illustrated in FIGS. 10 and 11, the only difference or one difference from the display device 100 according to the example embodiment illustrated in FIGS. 1 to 7 is that the device is a tiling display device, and other configurations are substantially the same, so redundant descriptions will be omitted or may be briefly provided. In addition, the same reference numerals will be used for the same configurations, and the descriptions for the same reference numerals can be referred to in FIGS. 1 to 7.

Referring to FIGS. 10 and 11, the display device 200 for displaying three-dimensional images according to another example embodiment of the present disclosure can include tiled display panels 210a, 210b, 210c, 210d, and 210e disposed above a support plate 101, and a lens 230 disposed above the display panels 210a, 210b, 210c, 210d, and 210e.

The display panels 210a, 210b, 210c, 210d, and 210e can be micro light emitting diode display panels, but are not limited thereto.

The display panels 210a, 210b, 210c, 210d, and 210e can be stretchable display panels.

The display device 200 for displaying three-dimensional images according to another example embodiment of the present disclosure is configured with tiled display panels 210a, 210b, 210c, 210d, and 210e, but is driven as if images are driven on a single screen, so that image information can be effectively provided to many people in public places.

In particular, since a large display device, for example, a display device of 100 inches or more, is installed for a special purpose and the demand is not constant, rather than implementing a large display device with a single display, tiled display panels 210a, 210b, 210c, 210d, and 210e formed by combining a plurality of display panels 210a, 210b, 210c, 210d, and 210e into a form of a single display panel can be more practical.

The support plate 101 and the base layer 105 can each be formed as a single configuration, but are not limited thereto, and can also be formed in a plurality configurations corresponding to the plurality of display panels 210a, 210b, 210c, 210d, and 210e.

Meanwhile, a support member 270 forming a space apart from the lens 230 can be disposed between the plurality of display panels 210a, 210b, 210c, 210d, and 210e.

For example, the support member 270 can be integrally formed during injection molding of the base layer 105, or can be separately processed and attached to the base layer 105. In addition, the support member 270 can be formed on the top surfaces of the plurality of display panels 210a, 210b, 210c, 210d, and 210e.

The space between the plurality of display panels 210a, 210b, 210c, 210d, and 210e where the support member 270 is disposed and the lens 230 can be filled with air, but is not limited thereto, and the planarization layer of the example embodiment described above can also be disposed therein.

The example embodiments of the present disclosure can also be described as follows:

According to an aspect of the present disclosure, there is provided a display device for displaying three-dimensional images. The display device for displaying three-dimensional images can include a support plate, a base layer disposed above the support plate, a display panel disposed above the base layer and divided into a plurality of sub pixels each including a display element and a lens disposed above the display panel, the display element can be disposed along a focal surface of the lens.

The display device can further comprise a first adhesive layer between the base layer and the display panel.

The first adhesive layer can include an optically clear adhesive (OCA) or an optically clear resin (OCR).

The display element can include one of a micro light emitting diode (μ-LED) and an organic light emitting diode.

The display panel can be a stretchable panel having flexibility.

A top surface of the base layer can have an uneven profile along a focal surface of the lens.

The display panel can have components and layers including the display element disposed along the uneven profile of the top surface of the base layer.

The display device can further comprise a planarization layer disposed between the display panel and the lens.

The display device can further comprise a second adhesive layer disposed between the planarization layer and the lens.

The second adhesive layer can include an optically clear adhesive (OCA) or an optically clear resin (OCR).

The lens can be disposed side by side in a first direction and a second direction perpendicular to the first direction, and each of the sub pixels can extend in a direction inclined with respect to the first direction and the second direction.

The lens can include a lenticular lens.

Five sub pixels can overlap one of the lenses.

The display panel can include a tiled display panel in which a plurality of display panels is combined into a single panel.

The display device can further comprise a support member disposed between the plurality of display panels to define a predetermined space with the lens.

The support member can be disposed on top surfaces of the plurality of display panels.

The support member can be attached to the base layer between the plurality of display panels.

According to another aspect of the present disclosure, there is provided a display device for displaying three-dimensional images. The display device for displaying three-dimensional images can include a display panel disposed above a base layer and divided into a plurality of sub pixels each including a display element and a lens disposed above the display panel, a top surface of the base layer can have an uneven profile along a curvature of the lens, and the display element is disposed along the uneven profile of the base layer.

Although the example embodiments of the present disclosure have been described in detail with reference to the accompanying drawings, the present disclosure is not limited thereto and can be embodied in many different forms without departing from the technical concept of the present disclosure. Therefore, the example embodiments of the present disclosure are provided for illustrative purposes only but not intended to limit the technical concept of the present disclosure. The scope of the technical concept of the present disclosure is not limited thereto. Therefore, it should be understood that the above-described example embodiments are illustrative in all aspects and do not limit the present disclosure. All the technical concepts in the equivalent scope of the present disclosure should be construed as falling within the scope of the present disclosure.

What is claimed is:

1. A display device for displaying three-dimensional images, the display device comprising:
a support plate;
a base layer disposed above the support plate;
a display panel disposed above the base layer and divided into a plurality of sub pixels, each of the plurality of sub pixels including a display element; and
a lens disposed above the display panel,
wherein the display element in at least one of the plurality of sub pixels is disposed along a focal surface of the lens.

2. The display device according to claim 1, further comprising:
a first adhesive layer between the base layer and the display panel.

3. The display device according to claim 2, wherein the first adhesive layer includes an optically clear adhesive or an optically clear resin.

4. The display device according to claim 1, wherein the display element in the at least one of the plurality of sub pixels includes one of a micro light emitting diode and an organic light emitting diode.

5. The display device according to claim 1, wherein the display panel is a stretchable panel having flexibility.

6. The display device according to claim 1, wherein a top surface of the base layer has an uneven profile along a focal surface of the lens.

7. The display device according to claim 6, wherein the display panel has components and layers including the display element in the at least one of the plurality of sub pixels disposed along the uneven profile of the top surface of the base layer.

8. The display device according to claim 1, further comprising:
a planarization layer disposed between the display panel and the lens.

9. The display device according to claim 8, further comprising:
a second adhesive layer disposed between the planarization layer and the lens.

10. The display device according to claim 9, wherein the second adhesive layer includes an optically clear adhesive or an optically clear resin.

11. The display device according to claim 1, wherein the lens comprises a plurality of lenses disposed side by side in a first direction and a second direction perpendicular to the first direction, and
wherein each of the plurality of sub pixels extends in a direction inclined with respect to the first direction and the second direction.

12. The display device according to claim 1, wherein the lens includes a lenticular lens.

13. The display device according to claim 1, wherein the lens comprises a plurality of lenses, and all five sub pixels among the plurality of sub pixels overlap one of the plurality of the lenses.

14. The display device according to claim 1, wherein the display panel includes a tiled display panel in which a plurality of display panels are combined into a single panel.

15. The display device according to claim 14, further comprising:
a support member disposed between the plurality of display panels to define a predetermined space with the lens.

16. The display device according to claim 15, wherein the support member is disposed above top surfaces of the plurality of display panels.

17. The display device according to claim 15, wherein the support member is attached to the base layer between the plurality of display panels.

18. A display device for displaying three-dimensional images, the display device comprising:
a display panel disposed above a base layer and divided into a plurality of sub pixels, each of the plurality of sub pixels including a display element; and
a lens disposed above the display panel,
wherein a top surface of the base layer has an uneven profile along a curvature of the lens, and the display element in at least one of the plurality of sub pixels is disposed along the uneven profile of the base layer.

19. The display device according to claim 18, wherein a bottom surface of the display panel has an uneven profile that corresponds with the uneven profile of the top surface of the base layer.

20. The display device according to claim 18, wherein the top surface of the base layer has a concave or convex shape along a focal surface of the lens.
